(19) United States
(12) Patent Application Publication
(10) Pub. No.: US 2012/0134198 A1
(43) Pub. Date: May 31, 2012

(54) MEMORY SYSTEM

(75) Inventors: Koichiro Yamaguchi, Kanagawa-ken (JP); Jin Kashiwagi, Kanagawa-ken (JP)

(73) Assignee: KABUSHIKI KAISHA TOSHIBA, Tokyo (JP)

(21) Appl. No.: 13/306,175

(22) Filed: Nov. 29, 2011

(30) Foreign Application Priority Data
Nov. 30, 2010 (JP) P2010-267829

(51) Int. Cl. G11C 11/413; G11C 7/06; G11C 7/10

(52) U.S. Cl. 365/154; 365/189.15

(57) ABSTRACT

A memory system includes a memory cell array including a plurality of memory cells electrically connected to pairs of bit lines once a word line is activated; latch portions connected to respective pairs of bit lines; a sense amplifier connected to the latch portions; and a control circuit configured to control the latch portions for a reading operation in order that data in all memory cells connected to the word line, once selected, come to be held in the corresponding latch portions as a group.

### CROSS-REFERENCE TO RELATED APPLICATIONS

This application is based upon and claims the benefit of priority from prior Japanese Patent Application No. 2010-267829, filed Nov. 30, 2010, the entire contents of which are incorporated herein by reference.

### FIELD

Embodiments described herein relate generally to memory systems, and is applied to, for example, a semiconductor memory system including multiple types of memories integrated into a single chip.

### BACKGROUND

An example of a semiconductor memory system including multiple types of memories integrated into a single chip is a semiconductor memory system including a NAND flash memory (memory unit) and a SRAM (Static Random Access Memory) integrated in a single chip (see Japanese Patent Application Publication No. 2006-73141).

### BRIEF DESCRIPTION OF THE DRAWINGS

FIG. 1 is a block diagram showing a memory system of a first embodiment.

FIG. 2 is a circuit diagram showing a memory cell array of the first embodiment.

FIG. 3 is a block diagram showing an example of a connecting relationship among data RAMs, burst buffers, and an interface in the memory system of the first embodiment.

FIG. 4 is a circuit diagram of an example in which 16 pairs of bit lines are connected to each sense amplifier in the memory system of the first embodiment.

FIG. 5 is a flowchart diagram showing how the memory system of first embodiment operates.

FIG. 6A is a timing chart showing how the memory system of the first embodiment operates.

FIG. 6B is a timing chart showing how a memory system of the second modification operates.

### DETAILED DESCRIPTION

In general, according to one embodiment, a memory system includes (1) a memory cell array including a plurality of memory cells electrically connected to pairs of bit lines when a word line is activated; latch portions connected to respective pairs of bit lines; a sense amplifier connected to the latch portions; and a control circuit configured to control the latch portions for a reading operation so that data in all memory cells connected to the word line, once selected, come to be held in the corresponding latch portions as a group.

### First Embodiment

Referring to the drawings, description will be provided for a first embodiment. For the convenience of explanation, the same portions will be denoted by the same reference signs throughout all the drawings. In addition, dimensional ratios among portions are not limited to those indicated in the drawings.

### [Configuration of Memory System]

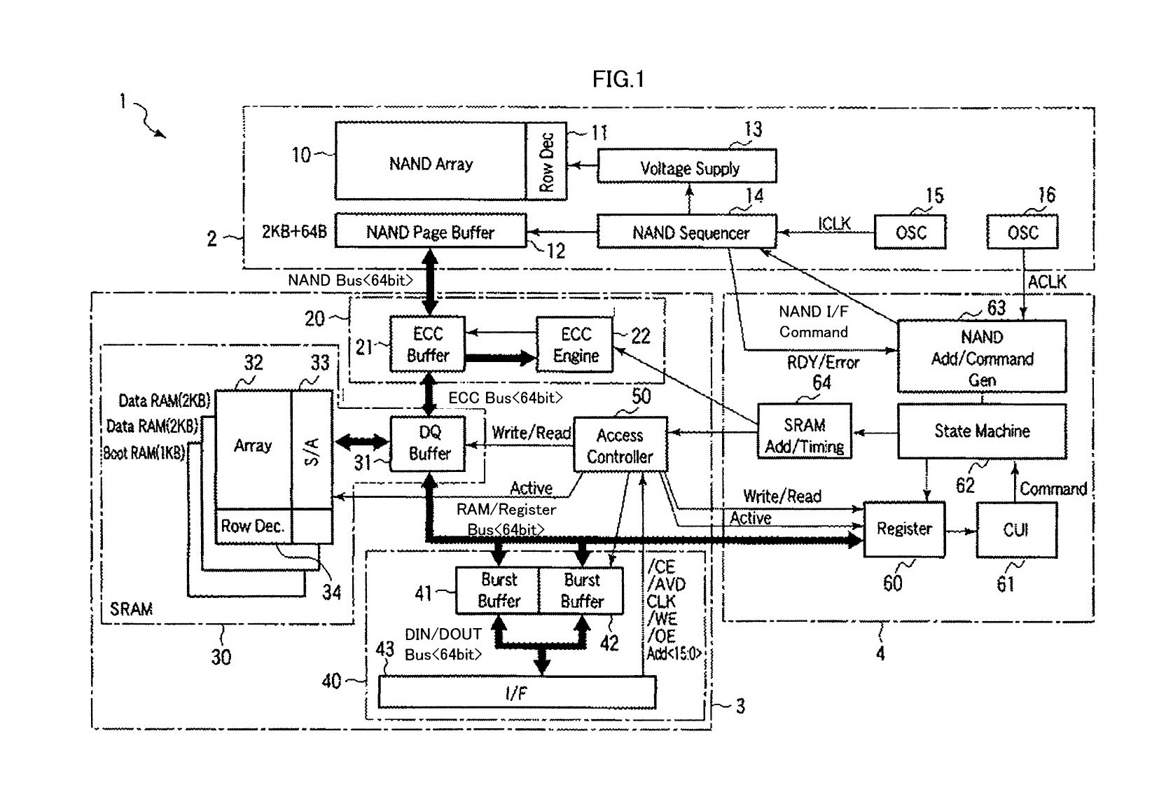

A memory system of the first embodiment will be described with reference to FIG. 1.

As shown in FIG. 1, a memory system 1 includes a NAND flash memory 2, an RAM unit 3, and a control unit 4. For example, in the memory system 1, the NAND flash memory 2, the RAM unit 3, and the control unit 4 are formed on the same semiconductor substrate, and are accordingly integrated in a single chip.

### <NAND Flash Memory>

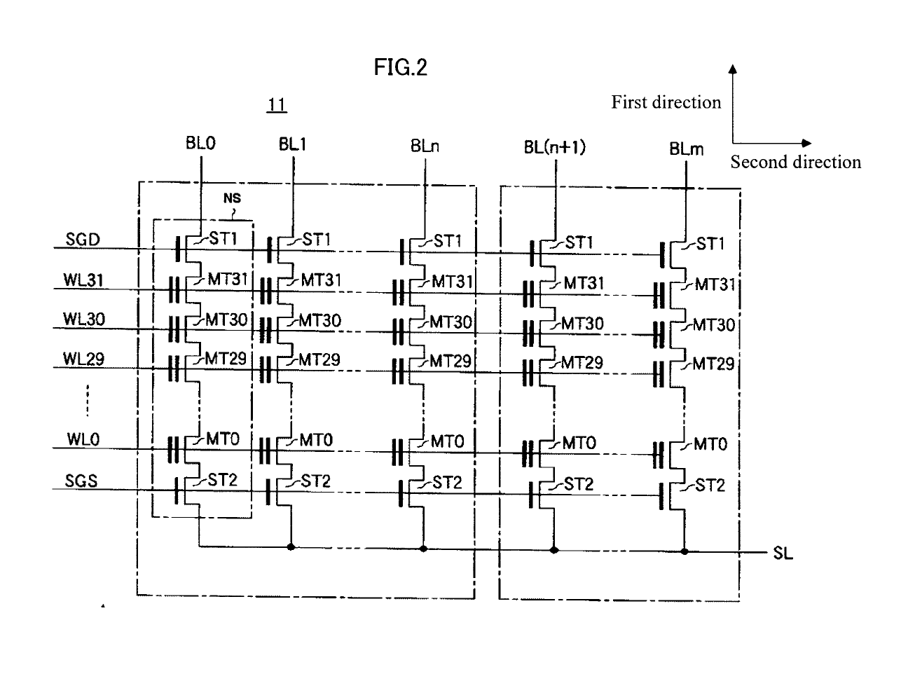

First of all, the NAND flash memory 2 will be described by use of FIG. 1 and a circuit diagram shown in FIG. 2.

The NAND flash memory 2 functions as a main memory unit of the memory system 1. As shown in FIG. 1, the NAND flash memory 2 includes a memory cell array 10, a row decoder 11, a page buffer 12, a column decoder, a voltage generating circuit 13, a sequencer (NAND Sequencer in FIG. 1) 14, and oscillators 15 and 16.

### <<Memory Cell Array>>

As shown in FIG. 2, the memory cell array 10 is formed from multiple NAND strings NS that are arrayed in a matrix. The memory cell array 10 includes: a first region for storing usual data; and a second region for storing data, the second region used as a spare region for the first region. For example, a parity for error correction is stored in the second region.

Multiple bit lines BL0 to BLm (“m” is natural number) are arranged, extending in a direction in which the NAND strings NS extend (i.e., in a first direction), over the NAND strings above a semiconductor substrate. The multiple bit lines BL0 to BLm are electrically connected to end portions of the NAND strings NS, respectively.

On the other hand, multiple word lines WL0 to WL31 are arranged, extending in a direction (second direction) orthogonal to the first direction, side-by-side at predetermined intervals in the first direction. In this respect, the first direction is concurrently a direction in which active regions extend.

Multiple selection gate lines SGS and SGD are arranged in parallel outside the respective word lines WL0 and WL31 with the multiple word lines WL0 to WL31 interposed in between.

Each NAND string NS includes multiple memory cells MT0 to MT31, and first and second selection gate transistors ST1 and ST2. Each memory cell MT has a stacked gate structure which includes: a charge storage layer formed above the semiconductor substrate with a gate insulating film interposed in between; and a control gate formed above the charge storage layer with an inter-gate insulating film interposed in between. Incidentally, the number of memory cells MT is not limited to 32, and may be any one of 8, 16, 34, 128, 256, etc. No specific restriction is imposed on the number of memory cells MT. In addition, each memory cell transistor MT may have a MONOS (Metal Oxide Nitride Oxide Silicon) structure that is obtained by a method of trapping electrons in a nitride film, instead of the stacked gate structure.

Each multiple memory cell MT0 to MT31 is formed in a portion corresponding to an intersection between the word lines WL and the corresponding bit line BL, and the memory cells are connected together in series in the direction in which the active regions extend (i.e., in the first direction).

In addition, as shown in FIG. 2, the first selection gate transistors ST1 on the side of the bit lines BL are connected to the memory cells MT31 in series, respectively. The second selection gate transistors ST2 on the side of the source lines SL are connected to the memory cells MT0 in series, respectively. The source line SL is commonly connected to the NAND strings NS.

As shown in FIG. 2, the control gates of each corresponding memory cell MT arranged in the second direction throughout all the NAND strings NS are commonly connected to a corresponding word line WL. In addition, the control gates of the first selection gate transistors ST1 arranged in the second direction are connected to the first selection gate line SGD. The control gates of the second selection gate transistors ST2 arranged in the second direction are connected to the second selection gate line SGS.

The multiple NAND strings NS are formed in a matrix in the memory cell array 10. Each set of memory cells MT sharing the same word line WL throughout all the NAND strings NS constitutes a page, which is a data reading/writing unit. Furthermore, each set of multiple NAND strings NS sharing the same word line WL constitutes a block, which is a data erasing unit.

### <<Page Buffer>>

The page buffer 12 is capable of holding one page of data. During a data read operation, the page buffer 12 temporarily holds data that is read from the memory cell array 10, and transfers the data to the RAM unit 3. In addition, during a data write operation, the page buffer 12 temporarily holds data to be written from the RAM unit 3, and transfers the data to the memory cell array 10.

A region in the page buffer 12 is used to hold main data, and the remaining region in the page buffer 12 is used to hold the parity, etc.

### <<Row Decoder and Column Decoder>>

The row decoder 11 selects a desired word line (s) WL in the memory cell array 10. In addition, the column decoder selects a desired column (s), namely, a desired bit line (s) BL in the memory cell array 10.

### <<Voltage Generating Circuit>>

The voltage generating circuit 13 generates a voltage needed to program, read, or erase data by raising or lowering a voltage given from the outside. Thus, the voltage generating circuit 13 supplies the generated voltage to the row decoder 11, for example. Hence, the voltage generated by the voltage generating circuit 13 is applied to a word line(s) WL.

<<Sequencer>>

The sequencer 14 controls the operation of the NAND flash memory 2 as a whole. Once receiving a NAND interface command (“NAND I/F command”) from the control unit 4, the sequencer 14 executes a sequence corresponding to the NAND interface command (for example, a sequence for programming data). In accordance with the sequence, the sequencer 14 controls the operation of the page buffer 12, the operation of the voltage generating circuit 13, etc. The sequencer 14 operates in synchronism with an internal clock ICLK transferred to the sequencer 14 from the oscillator 15, which will be described below.

<<Oscillators>>

The oscillator 15 (clock generator) generates the internal clock ICLK. The oscillator 15 transfers the generated internal clock ICLK to the sequencer 14.

The oscillator 16 (clock generator) generates the other internal clock ACLK. The oscillator 16 transfers the generated internal clock ACLK to the control unit 4, etc. The internal clock ACLK is a clock serving as a reference with which the controller 4 and the like operate in synchronism.

### <RAM Unit>

As shown in FIG. 1, the RAM unit 3 includes a ECC unit 20, an a interface unit (I/F unit in FIG. 1) 40 and an Access Controller 50.

### <<ECC Unit>>

During the data read operation, the ECC unit 20 detects and corrects an errors included in data that is read from the NAND flash memory 10. On the other hand, during the data write operation, the ECC unit 20 generates a parity for data that needs to be programmed.

The ECC unit 20 includes an ECC buffer 21 and an ECC engine 22. The ECC buffer 21 is connected to the page buffer 12 of the NAND flash memory 10 via the NAND data bus. Further, the ECC buffer 21 is connected to the SRAM unit 30 via the ECC data bus.

During the data read operation, the ECC buffer 21 holds data that is transferred from the page buffer 12, and transfers data, which finishes an ECC process (which finishes error correction during the data load operation), to the SRAM unit 30. On the other hand, during the data write operation, the ECC buffer 21 holds data that is transferred from the SRAM unit 30, and transfers data and the corresponding parity, which are transferred from the SRAM unit 30.

The ECC engine 22 performs an ECC process by use of data held in the ECC buffer 21. The ECC engine 22 employs, for example, a one-bit correction method using a Hamming code. In addition, the ECC engine 22 uses the minimum parity data needed for the correction process.

<<SRAM Unit>>

As shown in FIG. 1, the SRAM unit 30 includes a DQ buffer 31, multiple data RAMs, and a boot RAM. Each of the data RAMs and the boot RAM includes a memory cell array 32, a sense amplifier unit 33, and a row decoder 34. The capacity of each data RAM is 2K bytes, for example. The capacity of the boot RAM is 1K bytes, for example.

The multiple data RAM has multiple banks. Each bank has multiple SRAM memory cells in it. Word lines (for example, 32 word lines) connected to the SRAM memory cells are connected to the row decoder 34. Furthermore, pairs of bit lines (for example, 256 pairs of bit lines) connected to the SRAM memory cells are connected to the sense amplifier unit 33.

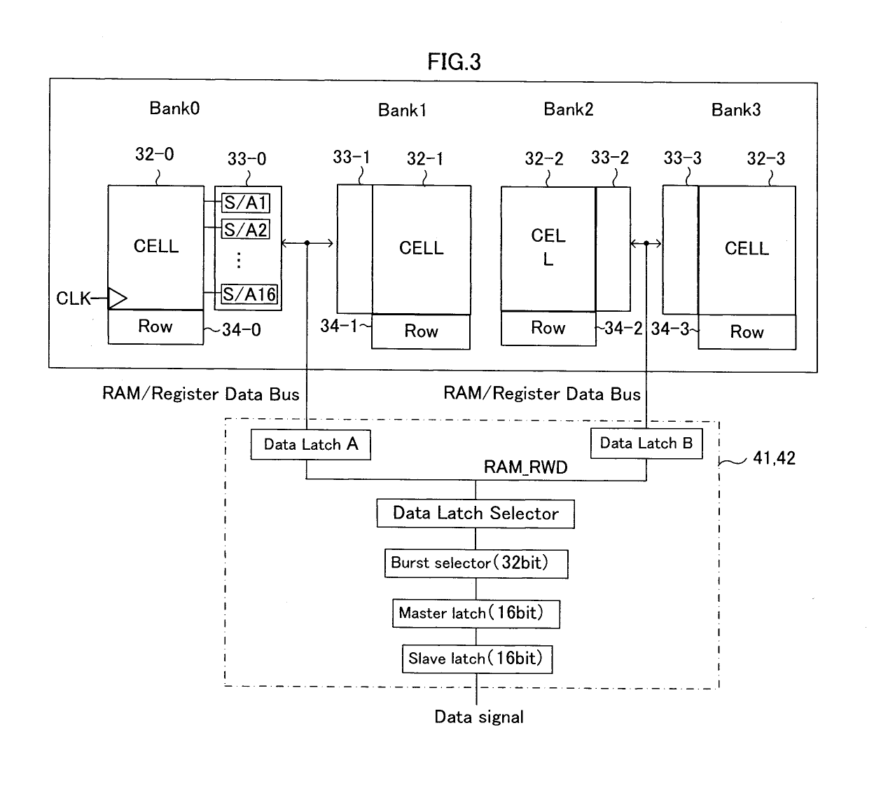

Each sense amplifier unit 33 includes multiple sense amplifiers. In a case where, as illustrated in FIG. 3, each sense amplifier unit 33 is connected to the 256 pairs of bit lines, the sense amplifier unit 33 includes 16 sense amplifiers (S/A1 through S/A16), and 16 pairs of bit lines are connected to each sense amplifier.

As in the memory cell array 10, the memory cell array 32 of each data RAM includes a region in which to hold main data and the other region in which to hold the parity, etc.

The sense amplifier unit 33 of each data RAM senses and amplifies data that is read from the SRAM cells to the pairs of bit lines BL, /BL. The row decoder 34 selects some out of the word lines WL of the memory cell array 32 in each data RAM.

<<Configuration between SRAM 30 and Interface Unit 40>>

Descriptions will be provided for a configuration between the SRAM unit 30 and the interface unit 40 by use of the example shown in FIG. 3. It should be noted that the DQ buffer 31 shown in FIG. 1 is omitted from FIG. 3. Furthermore, clocks CLK to be inputted into the bank 1 through the bank 3 are omitted from FIG. 3.

In a case where, as shown in FIG. 3, there are four banks, the output terminals of the sense amplifier units 33 of two banks are commonly connected together, while the output terminals of the sense amplifier units 33 of the other two banks are commonly connected together. As parallel signals, a signal from one of each paired banks is transferred to the burst buffer 41, and a signal from the other of the paired banks is transmitted to the burst buffer 42. In a case where data is read from two banks (for example, the bank 0 and the bank 1), the output terminals of whose sense amplifier units 33 are commonly connected together, data is outputted from the bank 0 when a clock is inputted into the bank 0. Subsequently, the 16th clock after the clock inputted into the bank 0 is inputted into the bank 1. Thereby, the data in the bank 0 and the data in the bank 1 are alternately outputted into the burst buffer 41 and the burst buffer 42.

In each bank, the SRAM memory cells are connected to the sense amplifiers S/A1 to S/A16. An address is set for each bank. In the case shown in FIG. 3, addresses A1 for the bank 0 and the bank 1 are set at 0 (zero), while addresses A1 for the bank 3 and the bank 4 are set at 1 (one).

As shown in FIG. 3, data latches A, B are circuits for storing data which is outputted from the memory cell arrays 32 to a RAM register data bus. In addition, a data latch selector is a circuit for switching its connection between the data latch A and the data latch B. A burst selector is a circuit that has a function of transferring data, which the burst selector receives from the data latch selector, to a master latch on the page-by-page basis, for example.

The data latch selector and the burst selector are controlled by receiving a selector address signal for determining which address should be selected, and a clock, from a burst read control circuit.

Each master latch and a slave latch are capable of holding a page of data. When a clock is inputted into the slave latch from the bust read control circuit, data is outputted from the slave latch to the interface 43.

### <<Configuration for Connecting SRAM Memory Cells and Sense Amplifiers>>

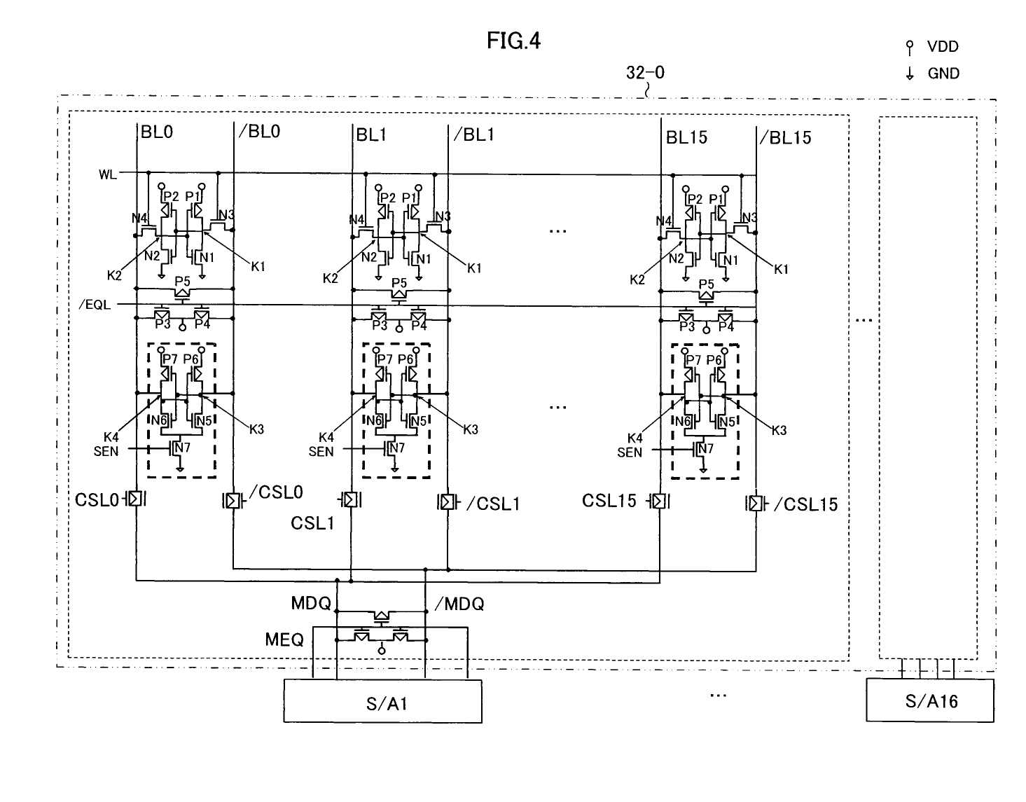

Next, using FIG. 4 showing a diagram of a circuit as an example, descriptions will be provided for a configuration for connecting the SRAM memory cells and the sense amplifiers. FIG. 4 shows an example circuit diagram in which 16 pairs of bit lines are connected to each sense amplifier. Incidentally, the word lines WL are represented by one word line WL for the sake of explanatory convenience.

Each SRAM memory cell has a configuration as shown in FIG. 4. A first CMOS inverter circuit and a second CMOS inverter circuit are provided in the SRAM memory cell in parallel. The first CMOS inverter circuit includes a P-channel MOS transistor P1 and an N-channel MOS transistor N1, and the second CMOS inverter circuit includes a P-channel MOS transistor P2 and an N-channel MOS transistor N2, between a power supply VDD and a ground potential GND. A flip-flop circuit having two storage nodes K1, K2 is made by cross-connecting the input and output terminals of the first CMOS inverter circuit to the output and input terminals of the second CMOS inverter circuit, respectively. One of N-channel MOS transistors N3, N4 each for performing an on/off operation in accordance with a binary level of the word line WL is provided between the storage node K2 and the bit line BL, and the other of the N-channel MOS transistors N3, N4 is provided between the storage node K1 and an inverse bit line /BL.

In addition, an equalizer line /EQL is commonly connected to each pair of bit lines BL, /BL in each bank in the SRAM memory cell array. Bit line pre-charging transistors (P-channel MOS transistors) P3, P4 for pre-charging the potentials of the pairs of bit lines BL, /BL by use of the power supply VDD and an equalizer-dedicated transistor (P-channel MOS transistor) P5 are provided between intersections between the equalizer line /EQL and each pair of bit lines BL, /BL.

Moreover, a latch circuit (a latch portion) is connected to each pair of bit lines BL, /BL in the SRAM memory cell array. The latch circuit has a configuration as follows.

The latch circuit has the configuration which is shown in FIG. 4. A third CMOS inverter circuit and a fourth CMOS inverter circuit are provided in the latch circuit in parallel. The third CMOS inverter circuit includes a P-channel MOS transistor P6 and an N-channel MOS transistor N5, and the fourth CMOS inverter circuit includes a P-channel MOS transistor P7 and an N-channel MOS transistor N6, between the power supply VDD and the ground potential GND. A flip-flop circuit having two storage nodes K3, K4 is made by cross-connecting the input and output terminals of the third CMOS inverter circuit and the output and input terminals of the fourth CMOS inverter circuit, respectively. The input terminals of the fourth and third inverter circuits are connected to the pair of bit lines BL, /BL, respectively. In addition, the drain of an N-channel MOS transistor N7 is connected to a common connection point between the N-channel MOS transistor N5 of the third inverter circuit and the N-channel MOS transistor N6 of the fourth inverter circuit. An internal control signal SEN is inputted into the gate of the N-channel MOS transistor N7, and the source of the N-channel MOS transistor N7 is connected to the ground potential GND.

Moreover, a pair of transfer gates are formed in each pair of bit lines BL, /BL. A necessary pair of bit lines BL, /BL are selected from the 16 pairs of bit lines BL, /BL connected to each sense amplifier by use of its corresponding pair of transfer gates. To put it specifically, an access controller 50 inputs an internal control signal CSL into the gate of the PMOS transistor in the transfer gate connected to the bit line BL, and inputs an internal control signal /CSL into the gate of the other PMOS transistor in the transfer gate connected to the bit line /BL. The access controller 50 inputs “H” as the internal control signal CSL and “L” as the internal control signal /CSL into a selected pair of bit lines BL, /BL. On the other hand, the access controller 50 inputs “L” as the internal control signal CSL and “H” as the internal control signal /CSL into the other unselected pairs of bit lines BL, /BL.

The boot RAM temporarily holds a boot code for activating the memory system 1, for example. The DQ buffer 31 temporarily holds data when the data is written into the data RAMs, or when the data is read from the data RAMs.

As shown in FIG. 1, the DQ buffer 31 is electrically connected to the ECC buffer 21 via an ECC bus. As a result, data can be transferred between the DQ buffer 31 and the ECC buffer 21.

In addition, use of the RAM/register bus enables data to be transmitted between the DQ buffer 31 and the burst buffers (the burst buffers shown in FIG. 1), which will be described later. The DQ buffer 31 includes a region in which to hold main data and a region in which to hold the parity, etc.

### <<Interface Unit>>

The interface unit 40 includes the burst buffers 41, 42, and an interface (an I/F shown in FIG. 1) 43.

The burst buffers 41, 42 are electrically connected to the DQ buffer 31 and the controller unit 4 via the RAM/Register bus. As a result, data can be transferred among the DQ buffer 31, the controller unit 4, and each of the burst buffers 41, 42.

The burst buffers 41, 42 are electrically connected to the interface 43 via a DIN/OUT bus. As a result, data can be transferred between the interface 43 and each of the burst buffers 41, 42. The burst buffers 41, 42 temporarily hold data that is given to the burst buffers 41, 42 from a host apparatus via the interface 43, or data that is given to the burst buffers 41, 42 from the DQ buffer 31.

The interface 43 can be connected to the host apparatus outside the memory system 1. The interface 43 controls the input and output of various signals, such as data, control signals, and addresses, to and from the host apparatus.

Examples of the signals include: a chip enable signal /CE for enabling the entire memory system 1, an address valid signal /AVD for latching an address, a clock CLK for a burst read, a write enable signal /WE for enabling a write operation, and an output enable signal /OE for enabling the output of data to the outside.

The interface 43 is electrically connected to the burst buffer 41, 42 via the DIN/OUT bus. The interface 43 transfers control signals from the host apparatus concerning a data read request, a load request, a write request, etc. to an access controller 50. For a data read operation, the interface 43 outputs data in the burst buffers 41, 42 to the host apparatus. For a data write operation, the interface 43 transfers data, which is given to the interface 43 from the host apparatus, to the burst buffers 41, 42.

### <<Access Controller>>

The access controller 50 receives a control signal and an address from the interface 43. In response, the access controller 50 controls the SRAM 30 and the control unit 4 in order for an operation, which satisfies a request of the host apparatus, to be executed.

To put it specifically, in response to the request from the host apparatus, the access controller 50 puts either the SRAM 30 or a register 60 inside the controller unit 4 in an active state. Subsequently, the access controller 50 issues a write command or a read command of data (denoted by reference sign Write/Read in FIG. 1) to the SRAM 30, or a write command or a read command (denoted by reference sign Write/Read in FIG. 1; hereinafter referred to as a “register write command” or a “register read command”) to the register 60. As a result, the buffer unit 21 or the controller unit 4 starts its operation.

### <Controller Unit>

As shown in FIG. 1, the controller unit 4 includes the register 60, a CUI (Command User Interface) 61, a state machine 62, an address/command generator circuit 63, and an address/timing generator circuit 64.

### <<Register>>

The register 60 sets up an operational status of a function. The register 60 allocates part of an external address space to this end. Thereby, the external host apparatus reads or writes either an address signal or a control signal, such as a command, from and to the allocated part of the external address space of the register 60 via the interface 43.

### <<CUI>>

Once the address signal or the control signal, such as a command, is written into the predetermined part of the external address space of the register 60, the CUI 61 recognizes that a function execution command is given to the CUI 61, and issues an internal command signal.

### <<State Machine>>

Upon reception of a command issued from the address/command generator circuit 63, which will be described later, or the internal command signal from the CUI 61, the state machine 62 controls an internal sequence operation, depending on the type of command.

### <<Address/Command Generator Circuit>>

The address/command generator circuit 63 generates an address signal and a control signal, such as a command, to the NAND flash memory 2 as necessary during the internal sequence operation.

### <<Address/Timing Generator Circuit>>

The address/timing generator circuit 64 generates an address and a control signal, such as a signal representing timing, for controlling the SRAM 30, as necessary during the internal sequence operation.

### [Method of Operating the Memory System]

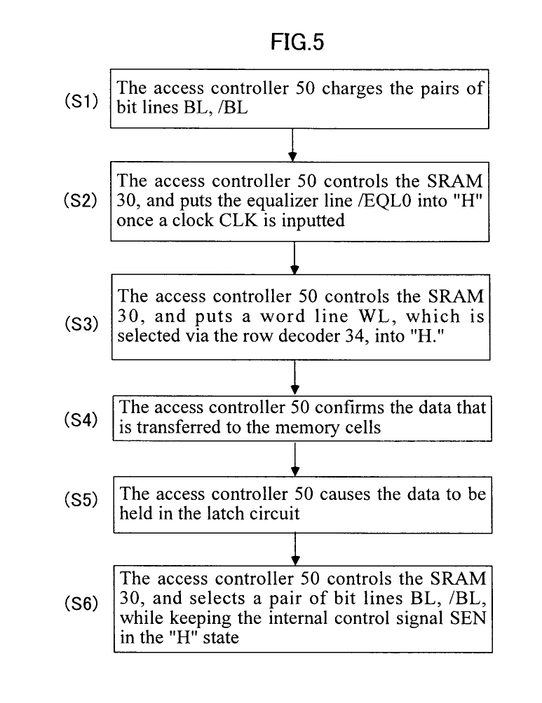

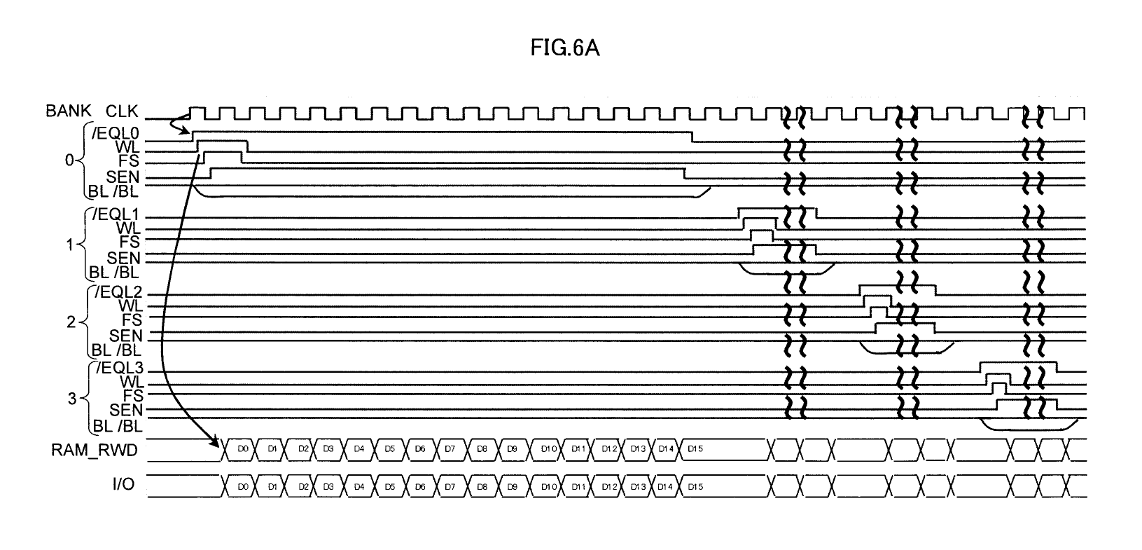

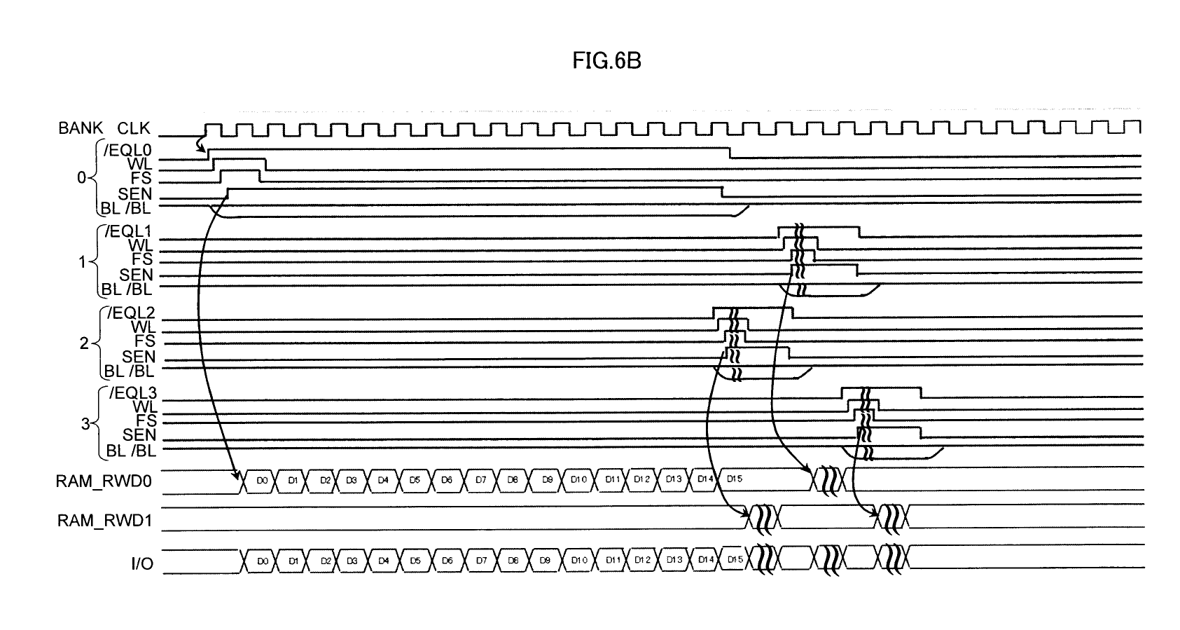

Next, as part of a method of operating the memory system of the first embodiment, the operation of the memory system until data in the SRAM memory cells connected to one word line WL inside the bank 0 shown in FIGS. 3 and 4 is read to the sense amplifier S/A will be described by use of a flowchart diagram shown in FIG. 5 and a timing chart shown in FIG. 6A. Incidentally, the descriptions will be provided on the assumption that data is beforehand stored in the SRAM memory cells.

First, in step S1, upon reception of a command from the interface 43, the access controller 50 charges all the pairs of bit lines BL, /BL inside the bank 0. For example, the access controller 50 charges the pairs of bit lines BL, /BL by making control in order that the transistors connected to MDQ and /MDQ, as shown in FIG. 4, can be put into an “ON” state.

Subsequently, in step S2, the access controller 50 controls the SRAM 30, and puts the equalizer line /EQL0 of the bank 0 into “H” once a clock CLK is inputted into the bank 0 via the row decoder 34. In response, the P-channel transistors connected to the equalizer line /EQL turn into an “OFF” state, and the pairs of bit lines BL, /BL enter a floating state.

In step S3, the access controller 50 controls the SRAM 30, and puts a word line WL, which is selected in the bank 0 via the row decoder 34, into “H.” Thereby, data of all the memory cells connected to the selected word line WL (for example, 256-bit data) is transferred to the pairs of bit lines BL, /BL in the floating state. Thereafter, as shown in FIG. 6A, the access controller 50 controls the SRAM 30, and inputs an internal control signal FS into the bank 0 via the row decoder 34. Thus, the access controller 50 confirms the data that is transferred to the memory cells (step S4).

The internal control signal FS is a signal inputted to confirm data. The internal control signal FS is designed to be inputted when the electric potential difference between paired bit lines BL, /BL exceeds a predetermined electric potential difference.

Let us assume that, for example, “1” is held in one SRAM memory cell. In other words, let us assume that the node K1 of one SRAM memory cell is put in “L” while the node K2 of the same SRAM memory cell is put in “H.” In this case, the MOS transistor P1 is off, the MOS transistor P2 is on, the MOS transistor N1 is on, and the MOS transistor N2 is off. Once a word line WL is connected to this SRAM memory cell, “H” is inputted into the gates of the respective N-channel MOS transistors N3, N4. Thereby, the N-channel MOS transistors N3, N4 are put into an “ON” state. When the word line WL is selected, the SRAM memory cell is electrically connected to the corresponding latch circuit. Thus, the bit line BL is kept charged, while the bit line /BL is discharged. Once the electric potential difference between the pair of bit lines BL, /BL exceeds the predetermined electric potential difference, data is confirmed by an internal control signal FS. Thereafter, the access controller 50 controls the SRAM 30, and inputs an internal control signal SEN, which is put in an “H” state, into the latch circuit. Thus, the access controller 50 causes the data to be held in the latch circuit (step S5). The data held in the pair of bit lines BL, /BL come to be held in the latch circuit. The data can be held by keeping the sources of the respective N-channel MOS transistors N5, N6 at the ground potential with the internal control signal SEN put in the “H” state. In other words, the data held in the nodes K1, K2 are transferred to the nodes K3, K4 in the latch circuit. Thereby, the data held in the SRAM memory cell comes to be held in the latch circuit. After data of all the memory cells connected to the word line WL are held in the corresponding latch circuits, the internal control signal FS is put into an “L” state, and the word line WL is put into “L.” (see FIG. 6A)

In step S6, the access controller 50 controls the SRAM 30, and selects a pair of bit lines BL, /BL by inputting a desired internal control signal into a pair of transfer gates CSL, /CSL connected to the pair of bit lines BL, /BL inside the bank 0, while keeping the internal control signal SEN in the “H” state. In other words, in the case shown in FIG. 4, one-bit data is transferred to the corresponding sense amplifier S/A, and 16-bit data is transferred to the burst buffers 41, 42 in the sense amplifier unit 33.

In this regard, the pairs of bit lines BL, /BL are sequentially selected with the internal control signal SEN kept in “H,” until all the data held in the SRAM memory cells connected to the selected word line WL is transferred to the burst buffers 41, 42. For example, in order to hold 256-bit data in the latch circuits in the bank 0, the selection and non-selection of the pairs of bit lines BL, /BL are carried out 16 times.

Thereby, the data held in the SRAM memory cells connected to one word line WL in the bank 0 can be read to the corresponding sense amplifier S/A.

In the embodiment shown in FIG. 6A, data held in the banks 0 to 3 are read in the sequence from the bank 0, the bank 1, the bank 2, and the bank 3 by repeating the foregoing operations.

### Effects of First Embodiment

By employing the foregoing configuration and operations, the first embodiment can provide a memory system configured to reduce the power consumption while reading data from the SRAM memory unit. Detailed descriptions will be hereinbelow provided.

The memory system of the first embodiment sequentially selects necessary pairs of bit lines BL, /BL while keeping the internal control signal SEN of the corresponding latch circuits in “H.” Thereby, the memory system is configured to read data held in the latch circuits corresponding to all the memory cells connected to a selected word line WL. For example, in order to hold 256-bit data in latch circuits in the bank 0, the memory system carries out 16 times of selection and non-selection of the pairs of bit lines BL, /BL. In this process, the memory system is configured to read the data from all the memory cells connected to one selected word line WL with the word line electrically charged only once, instead of repeatedly charging and discharging the word line WL each time the selection and non-selection are switched among the pairs of bit lines BL, /BL. As a result, the memory system no longer needs to recharge the word line WL repeatedly while reading the data. Accordingly, the memory system can reduce the power consumption. In addition, because the memory system of the first embodiment sequentially selects necessary pairs of bit lines BL, /BL while keeping the internal control signal SEN of the corresponding latch circuits in “H,” the memory system is configured to read the data without carrying out equalization each time the selection and non-selection of the pairs of bit lines BL, /BL are changed. As a result, the memory system no longer needs to recharge the word line WL repeatedly while reading the data. Accordingly, the memory system can reduce the power consumption.

Thus, the memory system of the first embodiment can reduce the power consumption while reading the data from the SRAM memory unit.

### <Modification 1>

The memory system of the first embodiment puts the selected word line WL into “L,” once the memory system causes the data held in all the memory cells connected to a selected word line WL to be held in the corresponding latch circuits. Furthermore, the memory system puts the internal control signal SEN into “H” when reading the data from the latch circuits. As opposed to the memory system of the first embodiment, a memory system of Modification 1 is designed to keep the word line WL in “H” and the internal control signal SEN in “L” until the memory system finishes reading the data from all the memory cells connected to the selected word line WL to the burst buffers 41, 42.

### <Modification 2>

The memory system of the first embodiment reads data, which is held in the banks 0 to 3, to the external host apparatus in the sequence from the bank 0, the bank 1, the bank 2, and the bank 3. As opposed to the memory system of the first embodiment, a memory system of Modification 2 transfers data from a certain bank 0, and thereafter transfers data from another bank, the output terminal of whose sense amplifier unit is not commonly connected to the output terminal of the sense amplifier unit 33 of the certain bank 0, when the memory system has multiple sets each consisting of two banks, the output terminals of whose sense amplifier units 33 are commonly connected together. For example, the memory system has two sets of banks, as shown in FIG. 3. For example, when, as shown in FIG. 3, the memory system has a connecting relationship among the data RAMS, the burst buffers, and the interface, the memory system transfers data from the bank 0, subsequently data from the bank 2, thereafter data from the bank 1, and afterward data from the bank 3, as shown in FIG. GB.

The sequential reading of data from the bank 0 and the bank 2, the output terminals of whose sense amplifiers units 33 are not commonly connected together, enables the memory system to charge the pairs of bit lines BL, /BL selected for reading data from the bank 2, while reading data from the bank 0. This makes it possible for the memory system of Modification 2 to read data faster than the memory system of the first example.

It should be noted that the first embodiment allows the word lines WL to be discharged at any time before the equalizer line /EQL is discharged and allows the timing of charging the word lines to be changed as necessary.

While certain embodiments have been described, these embodiments have been presented by way of example only, and are not intended to limit the scope of the inventions. Indeed, the novel embodiments described herein may be embodied in a variety of other forms. Furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system, comprising:
a memory cell array including a plurality of memory cells electrically connected to pairs of bit lines when a word line is activated;
latch portions connected to respective pairs of bit lines;
a sense amplifier connected to the latch portions; and
a control circuit configured to control the latch portions for a reading operation so that data in all memory cells connected to the word line, once selected, come to be held in the corresponding latch portions as a group.

2. A memory system, comprising:
a first bank including
a first memory cell array including a plurality of first memory cells electrically connected to pairs of first bit lines when a first word line is activated,
first latch portions connected to respective pairs of first bit lines, and
a first sense amplifier connected to the first latch portions;
a second bank different from the first bank, the second bank including
a second memory cell array including a plurality of second memory cells electrically connected to pairs of second bit lines when a second word line is activated,
second latch portions connected to respective pairs of second bit lines, and
a second sense amplifier connected to the second latch portions;
a buffer circuit to which the first sense amplifier and the second sense amplifier are commonly connected; and
a control circuit configured to control the first or second latch portions for a reading operation so that data in all memory cells connected to a selected one of the first word line or the second word line is held in the corresponding first latch portions or the corresponding second latch portions as a group.

3. The memory system of claim 1, wherein
the latch portions respectively include first transistors, an end of an electric current path of each first transistor being grounded; and
the control circuit is configured to cause the first transistors to be put into an “ON” state when the data in the memory cells come to be held in the latch portions.

4. The memory system of claim 2, wherein
the latch portions respectively include first transistors, an end of an electric current path of each first transistor being grounded; and
the control circuit is configured to cause the first transistors to be put into an “ON” state when the data in the memory cells come to be held in the latch portions.

5. The memory system of claim 3, wherein
for the reading operation, the control circuit is configured to cause the first transistors to be put into the “ON” state after electrically connecting the memory cells and the corresponding latch portions together by selecting the word line.

6. The memory system of claim 4, wherein
for the reading operation, the control circuit is configured to cause the first transistors to be put into the “ON” state after electrically connecting the memory cells and the corresponding latch portions together by selecting the word line.

7. The memory system of claim 2, further comprising:
a third bank different from the first bank and the second bank, the third bank including
a third memory cell array including a plurality of third memory cells electrically connected to pairs of third bit lines when a third word line is activated,
third latch portions connected to respective pairs of third bit lines, and
a third sense amplifier connected to the third latch portions; and
a fourth bank different from the first to third banks, the fourth bank including
a fourth memory cell array including a plurality of fourth memory cells electrically connected to pairs of fourth bit lines when a fourth word line is activated,
fourth latch portions connected to respective pairs of fourth bit lines, and
a fourth sense amplifier connected to the fourth latch portions,
wherein the third sense amplifier and the fourth sense amplifier are further commonly connected to the buffer circuit; and
the control circuit is configured to read data in any one of the first bank and the second bank to the buffer circuit, and thereafter reads data in any one of the third bank and the fourth bank to the buffer circuit.

8. The memory system of claim 4, further comprising:
a third bank different from the first bank and the second bank, the third bank including
a third memory cell array including a plurality of third memory cells electrically connected to pairs of third bit lines when a third word line is activated,
third latch portions connected to respective pairs of third bit lines, and
a third sense amplifier connected to the third latch portions; and
a fourth bank different from the first bank to the third bank, the fourth bank including
a fourth memory cell array including a plurality of fourth memory cells electrically connected to pairs of fourth bit lines when a fourth word line is activated,
fourth latch portions connected to respective pairs of fourth bit lines, and
a fourth sense amplifier connected to the fourth latch portions,
wherein the third sense amplifier and the fourth sense amplifier are further commonly connected to the buffer circuit, and
the control circuit is configured to read data in any one of the first bank and the second bank to the buffer circuit, and thereafter reads data in any one of the third bank and the fourth bank to the buffer circuit.

9. The memory system of claim 6, further comprising:
a third bank different from the first bank and the second bank, the third bank including
a third memory cell array including a plurality of third memory cells electrically connected to pairs of third bit lines when a third word line is activated,
third latch portions connected to respective pairs of third bit lines, and
a third sense amplifier connected to the third latch portions; and
a fourth bank different from the first to third banks, the fourth bank including
a fourth memory cell array including a plurality of fourth memory cells electrically connected to pairs of fourth bit lines when a fourth word line is activated,
fourth latch portions connected to respective pairs of fourth bit lines, and
a fourth sense amplifier connected to the fourth latch portions,
wherein the third sense amplifier and the fourth sense amplifier are further commonly connected to the buffer circuit; and
the control circuit is configured to read data in any one of the first bank and the second bank to the buffer circuit, and thereafter to read data in any one of the third bank and the fourth bank to the buffer circuit.

10. The memory system of claim 8, wherein
while reading the data in any one of the first bank and the second bank to the buffer circuit, the control circuit causes the pairs of third bit lines or the pairs of fourth bit lines to be electrically charged.

11. The memory system of claim 9, wherein
while reading the data in any one of the first bank and the second bank to the buffer circuit, the control circuit causes the pairs of third bit lines or the pairs of fourth bit lines to be electrically charged.

12. The memory system of claim 8, wherein
the control circuit is configured to read the data in any one of the third bank and the fourth bank to the buffer circuit, and thereafter to read the data in any one of the first bank and the second bank to the buffer circuit.

13. The memory system of claim 10, wherein
the control circuit is configured to read the data in any one of the third bank and the fourth bank to the buffer circuit, and thereafter to read the data in any one of the first bank and the second bank to the buffer circuit.

14. The memory system of claim 11, wherein
the control circuit is configured to read the data in any one of the third bank and the fourth bank to the buffer circuit, and thereafter to read the data in any one of the first bank and the second bank to the buffer circuit.

15. The memory system of claim 3, wherein each of the latch portions includes
a first inverter circuit including a first N-channel MOS transistor and a first P-channel MOS transistor; and
a second inverter circuit including a second N-channel MOS transistor and a second P-channel MOS transistor, wherein
a flip-flop circuit having two storage nodes is formed by cross-connecting input and output terminals of the first inverter circuit to output and input terminals of the second inverter circuit, respectively;
the input terminals of the first and second inverter circuits are connected to the corresponding pair of bit lines;
sources of the first and second P-channel MOS transistors are connected to a common power supply line;
sources of the first and second N-channel MOS transistors are connected to a drain of the corresponding first transistor;
a source of the first transistor is grounded; and
the first transistor is turned on and off based on an internal control signal inputted into a gate of the first transistor.

16. The memory system of claim 4, wherein each of the latch portions includes
a first inverter circuit including a first N-channel MOS transistor and a first P-channel MOS transistor; and
a second inverter circuit including a second N-channel MOS transistor and a second P-channel MOS transistor, wherein
a flip-flop circuit having two storage nodes is formed by cross-connecting input and output terminals of the first inverter circuit to output and input terminals of the second inverter circuit, respectively;
the input terminals of the first and second inverter circuits are connected to the corresponding pair of bit lines;
sources of the first and second P-channel MOS transistors are connected to a common power supply line;
sources of the first and second N-channel MOS transistors are connected to a drain of the corresponding first transistor;
a source of the first transistor is grounded; and
the first transistor is turned on and off based on an internal control signal inputted into a gate of the first transistor.

17. The memory system of claim 7, wherein each of the latch portions includes
a first inverter circuit including a first N-channel MOS transistor and a first P-channel MOS transistor; and
a second inverter circuit including a second N-channel MOS transistor and a second P-channel MOS transistor, wherein
a flip-flop circuit having two storage nodes is formed by cross-connecting input and output terminals of the first inverter circuit to output and input terminals of the second inverter circuit, respectively;
the input terminals of the first and second inverter circuits are connected to the corresponding pair of bit lines;
sources of the first and second P-channel MOS transistors are connected to a common power supply line;
sources of the first and second N-channel MOS transistors are connected to a drain of the corresponding first transistor;
a source of the first transistor is grounded; and
the first transistor is turned on and off on the basis of an internal control signal inputted into a gate of the first transistor.

18. The memory system of claim 1, wherein the memory cells are SRAMs.

19. The memory system of claim 2, wherein the memory cells are SRAMs.

20. A memory system, comprising:
a memory cell array including a plurality of memory cells electrically connected to pairs of bit lines when a word line is activated;
latch means for latching a data hold in the memory cell array;
sense means for sensing data; and
control means for controlling the latch means for a reading operation so that data in all memory cells connected to the word line, once selected, come to be held in the corresponding latch means as a group.
